(19) United States
(12) Patent Application Publication
(10) Pub. No.: US 2023/0117607 A1
(43) Pub. Date: Apr. 20, 2023

(54) Semiconductor Device and Method of Manufacturing the Same

(71) Applicant: Nippon Telegraph and Telephone Corporation, Tokyo (JP)

(72) Inventors: Takuya Tsutsumi, Musashino-shi, Tokyo (JP); Hideaki Matsuzaki, Musashino-shi, Tokyo (JP)

(21) Appl. No.: 17/914,645

(22) PCT Filed: May 11, 2020
(86) PCT No.: PCT/JP2020/018776

§ 371 Date: Sep. 26, 2022

(51) Int. Cl. H01L 29/51; H01L 29/66; H01L 29/778; H01L 29/423; H01L 29/40

(52) U.S. Cl. CPC H01L 29/511; H01L 29/66431; H01L 29/7786; H01L 29/42364; H01L 29/517; H01L 29/401; H01L 29/41775

(57) ABSTRACT

A semiconductor device (field effect transistor) includes a gate insulating layer between both of a bottom part and a lateral surface of a recess part and a penetration portion of a gate electrode. The gate insulating layer is composed of an oxide of a substance which a barrier layer is composed of For example, the gate insulating layer is composed of a layer of In oxide and a layer of Al oxide.

### TECHNICAL FIELD

The present invention relates to a semiconductor device composed of compound semiconductor and a manufacturing method of the same.

### BACKGROUND ART

Properties of terahertz waves in a frequency band of 0.3 to 3.0 THz of electromagnetic waves lead to a potential of unprecedented and novel applications such as high-speed wireless communication at over tens of gigabits per second, non-destructive internal inspection with three-dimensional imaging, and component analysis using electromagnetic wave absorption.

When an application of terahertz waves is to be realized, an electronic device constituting this is also needed to have more excellent high frequency characteristics. In general, as electronic devices having excellent high frequency characteristics, there are used field effect transistors a material of which is compound semiconductor having particularly high electron mobility in terms of physical property.

The aforementioned field effect transistor is composed of a semiconductor substrate, a semiconductor stacking structure formed on the semiconductor substrate, a gate electrode formed on the surface of the semiconductor stacking structure, and a source electrode and a drain electrode which are formed on both sides of the gate electrode. In particular, a high electron mobility transistor excellent in high frequency characteristics is composed by stacking a buffer layer, a channel layer, a barrier layer, a stopper layer, a cap layer, and a passivation layer sequentially from the side of the semiconductor substrate. Moreover, a carrier supply layer is formed on the barrier layer side relative to the channel layer or on the buffer layer side relative to the channel layer. In this configuration, the position of the carrier supply layer and the amount of doping with an impurity are designed in accordance with the design of characteristics of the device.

With this sort of field effect transistor, when a potential is applied to the gate electrode, depending on the intensity of the applied potential, the concentration of two-dimensional electron gas is modulated, the electron gas being formed by supplying carriers from the carrier supply layer to the channel layer, and electrons move through a conduction channel formed between the source electrode and the drain electrode. The channel layer in which the conduction channel which these electrons (carriers) move (travel) through is formed is spatially separate from the carrier supply layer, which restrains scattering due to the impurity in the carrier supply layer. Therefore, with the aforementioned field effect transistor, electron mobility can be improved and high frequency operation can be realized.

In order to improve the high frequency characteristics of the field effect transistor, it is important to restrain a short channel effect and it is effective to shorten the distance between the gate electrode and the channel. However, simply shortening the distance between the gate electrode and the channel decreases the thickness of the barrier as viewed from electrons at the gate electrode, which causes tunneling of electrons to occur and increases a leak current from the gate electrode.

In order to handle this problem, employing a MOS-type field effect transistor is a typical measure by forming a gate oxide layer having a large barrier height between the gate electrode and the barrier layer. Composing the gate insulating layer of a material with a higher dielectric constant than that of the barrier layer makes the effective thickness of the gate insulating layer small. In the technology disclosed in Non-Patent Literature 1, the barrier layer is etched in high accuracy by wet processing to reduce the distance between the gate electrode and the barrier layer. In this technology, the gate insulating layer is formed by depositing a material having a high dielectric constant by an atomic layer deposition method subsequently from the etching processing of the barrier layer. With the technology disclosed in Non-Patent

Literature 1, a MOS-type field effect transistor having excellent characteristics is realized according to the above.

### CITATION LIST

### Non-Patent Literature

Non-Patent Literature 1: J. Lin et al., “A Novel Digital Etch Technique for Deeply Scaled III-V MOSFETs”, IEEE Electron Device Letters, vol. 35, no. 4, pp. 440-442, 2014.

### SUMMARY OF THE INVENTION

Technical Problem

However, the aforementioned technology decreases the throughput of the production process since the atomic layer deposition method is applied to formation of the gate insulating layer. The atomic layer deposition method is a technology of alternately repeating hydration of the surface of a deposition target and oxidation with precursor introduction to form an oxide layer on an atomic layer-by-atomic layer basis. Therefore, a considerable number of repetitions of the aforementioned cycles are needed in order to form the gate insulating layer having a desired film thickness, and decrease the throughput required for the production. There has been a problem as above that the conventional technology does not allow high throughput production of a MOS-type field effect transistor having the excellent characteristics.

The present invention is devised in order to solve a problem as above, and an object thereof is to make it possible to manufacture a MOS-type field effect transistor having excellent characteristics in high throughput.

### Means for Solving the Problem

A semiconductor device according to the present invention includes: a buffer layer, a channel layer, a barrier layer, and a carrier supply layer which are formed on a semiconductor substrate; a recess part formed, in the barrier layer, to a middle part of the barrier layer in a thickness direction; a gate electrode formed on the barrier layer such that a part of the gate electrode penetrates into the recess part; a source electrode and a drain electrode formed on the barrier layer such that the gate electrode is interposed between them; a cap layer formed between both of the source electrode and the drain electrode and the barrier layer; and a gate insulating layer formed between both of a bottom part and a lateral surface of the recess part and the gate electrode and composed of an oxide of a substance that the barrier layer is composed of.

Moreover, a manufacturing method of a semiconductor device according to the present invention includes: a first step of providing a state where a buffer layer, a channel layer, a barrier layer, a carrier supply layer, and a cap layer are formed on a semiconductor substrate; a second step of forming a source electrode and a drain electrode on the cap layer so as to be separate from each other; a third step of forming an opening in the cap layer that is in a gate formation region between the source electrode and the drain electrode, the opening penetrating through the cap layer; a fourth step of forming, in the barrier layer that is in a region of the opening, a recess part to a middle part of the barrier layer in a thickness direction; a fifth step of forming a gate insulating layer composed of an oxide of a substance that the barrier layer is composed of by oxidizing the barrier layer that is in a bottom part and a lateral surface of the recess part; and a sixth step of forming a gate electrode that is arranged on the barrier layer such that a part of the gate electrode penetrates into the recess part in which the gate insulating layer is formed.

### EFFECTS OF THE INVENTION

As described above, according to the present invention, since the gate insulating layer is used which is composed of an oxide of a substance which the barrier layer is composed of, MOS-type field effect transistors having excellent characteristics can be manufactured in high throughput.

### BRIEF DESCRIPTION OF DRAWINGS

FIG. 1 is a sectional view showing a configuration of a semiconductor device according to an embodiment of the present invention.

FIG. 2A is a sectional view showing a state of a semiconductor device according to an embodiment of the present invention in a middle step for explaining a manufacturing method of the semiconductor device.

FIG. 2B is a sectional view showing a state of the semiconductor device according to the embodiment of the present invention in a middle step for explaining the manufacturing method of the semiconductor device.

FIG. 2C is a sectional view showing a state of the semiconductor device according to the embodiment of the present invention in a middle step for explaining the manufacturing method of the semiconductor device.

FIG. 2D is a sectional view showing a state of the semiconductor device according to the embodiment of the present invention in a middle step for explaining the manufacturing method of the semiconductor device.

FIG. 2E is a sectional view showing a state of the semiconductor device according to the embodiment of the present invention in a middle step for explaining the manufacturing method of the semiconductor device.

### DESCRIPTION OF EMBODIMENTS

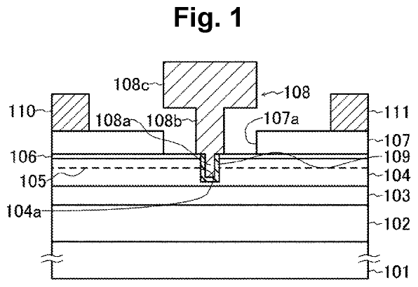

Hereafter, a semiconductor device according to an embodiment of the present invention is described with reference to FIG. 1. Notably, FIG. 1 shows a cross section thereof parallel to the gate length direction. This semiconductor device is a field effect transistor and includes a buffer layer 102, a channel layer 103, a barrier layer 104, a carrier supply layer 105, a gate electrode 108, a source electrode 110, and a drain electrode 111 which are formed on a semiconductor substrate 101. Notably, in the embodiment, the buffer layer 102, the channel layer 103, and the barrier layer 104 are stacked on the semiconductor substrate 101 in the order of these. Notably, the order of stacking the channel layer 103 and the barrier layer 104 is not limited to that in the aforementioned configuration.

The semiconductor substrate 101 is composed, for example, of semi-insulating InP. The buffer layer 102 is composed of InAlAs and is set to have 100 to 300 nm of layer thickness, for example. The channel layer 103 is composed of InGaAs and is set to have 5 to 20 nm of layer thickness, for example. The barrier layer 104 is composed of InAlAs and is set to have 5 to 20 nm of layer thickness, for example. The carrier supply layer 105 is formed in the barrier layer 104, for example, by well-known sheet doping, being doped with 1×10¹⁹ cm⁻³ of Si as an impurity. In the embodiment, the stopper layer 106 is provided on the barrier layer 104. The stopper layer 106 is composed of InP and is set to have 2 to 5 nm of layer thickness, for example. These can be formed through crystal growth, for example, by a metalorganic vapor phase epitaxy method, a molecular beam epitaxy method or the like.

This semiconductor device includes, in the barrier layer 104, a recess part 104a formed to the middle part of the barrier layer 104 in the thickness direction. The recess part 104a is a trench extending in the gate width direction. The gate electrode 108 is formed on the barrier layer 104 such that a part of the gate electrode 108 penetrates into the recess part 104a. The gate electrode 108 is shaped into a T shape in sectional view and includes a penetration portion 108a penetrating into the recess part 104a, a leg portion 108b which is continuously formed on the penetration portion 108a and the length of which in the gate length direction is small, and a head portion 108c which is continuously formed on the leg portion 108b and the length of which in the gate length direction is larger than that of the leg portion 108b. The gate electrode 108 can be composed, for example, of platinum or gold.

The source electrode 110 and the drain electrode 111 are formed on the barrier layer 104 such that the gate electrode 108 is interposed between them. The source electrode 110 and the drain electrode 111 can be composed, for example, of Ti/Pt/Au. Moreover, a cap layer 107 is formed between both the source electrode 110 and the drain electrode 111 and the barrier layer 104. The cap layer 107 is composed, for example, of InGaAs doped with 1×10¹⁹ to 2×10¹⁹ cm⁻³ of Si. An opening 107a is formed in the cap layer 107. The gate electrode 108 is arranged in the opening 107a.

Moreover, the semiconductor device (field effect transistor) according to the embodiment includes a gate insulating layer 109 between both of the bottom part and the lateral surface of the recess part 104a and the gate electrode 108 (penetration portion 108a). The gate insulating layer 109 is composed of an oxide of a substance which the barrier layer 104 is composed of. The gate insulating layer 109 is composed, for example, of a layer of In oxide and a layer of Al oxide.

In the state where the distance between the gate electrode 108 and the channel is simply shortened, the thickness of the barrier layer 104 as viewed from electrons of the gate electrode 108 decreases and tunneling of electrons occurs, which causes a leak current from the gate electrode 108 to increase. The gate insulating layer 109 is used in order to avoid this problem.

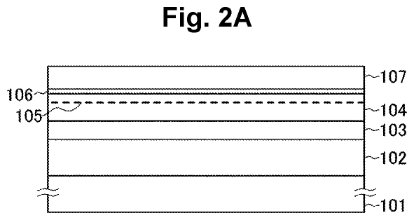

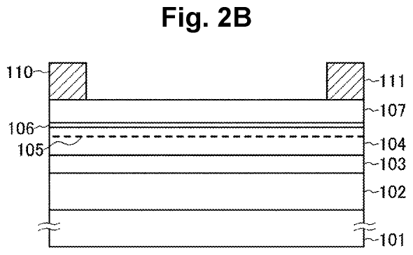

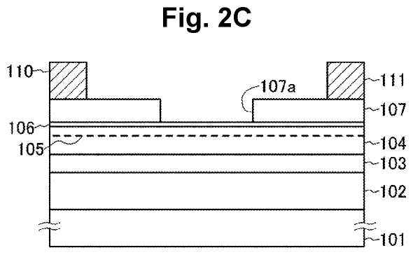

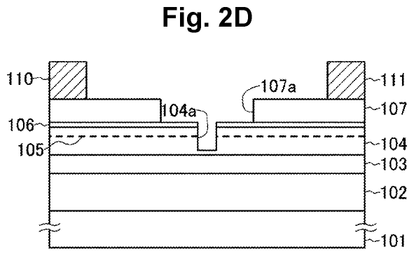

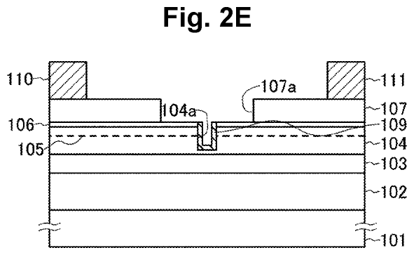

Next, a manufacturing method of a semiconductor device (field effect transistor) according to an embodiment of the present invention is described with reference to FIG. 2A to FIG. 2E. Notably, FIG. 2A to FIG. 2E show cross sections thereof parallel to the gate length direction.

First, as shown in FIG. 2A, the buffer layer 102, the channel layer 103, the barrier layer 104, the carrier supply layer 105, and the cap layer 107 are formed on the semiconductor substrate 101 (first step).

For example, the buffer layer 102, the channel layer 103, the barrier layer 104, and the cap layer 107 are sequentially stacked on the semiconductor substrate 101 through crystal growth by a metalorganic vapor phase epitaxy method, a molecular beam epitaxy method or the like. Moreover, the carrier supply layer 105 is formed in the barrier layer 104 by the sheet doping. Moreover, in the embodiment, the stopper layer 106 is formed between the carrier supply layer 105 and the cap layer 107. Moreover, for inter-element separation, a mesa region is formed through patterning by wet etching or dry etching.

Next, as shown in FIG. 2B, the source electrode 110 and the drain electrode 111 are formed on the cap layer 107 so as to be separate from each other (second step). The source electrode 110 and the drain electrode 111 are formed such that a region where the gate electrode 108 is to be formed is interposed between them. For example, the source electrode 110 and the drain electrode 111 are formed by depositing Ti/Pt/Au on the cap layer 107 to form a metal film and patterning this metal film by known photolithography technology and etching technology. Otherwise, the source electrode 110 and the drain electrode 111 can also be formed by a known lift-off method. The source electrode 110 and the drain electrode 111 make ohmic junction with the cap layer 107.

Next, as shown in FIG. 2C, the opening 107a penetrating through the cap layer 107 is formed in the cap layer 107 (third step). The opening 107a is formed by patterning the cap layer 107 by known lithography technology and etching technology.

For example, the opening 107a can be formed by selectively etching the cap layer 107 by wet etching using a mask pattern (not shown) of an insulating material, a resist or the like and using etching liquid with citric acid, phosphoric acid or the like as an etchant. With this etching, the stopper layer 106 composed of InP is scarcely etched with the aforementioned etching liquid to work as a layer for stopping the etching (stopper layer) and can prevent the barrier layer 104 from being etched. Using the stopper layer 106 as above enables etching with excellent controllability in the depth (thickness) direction. Notably, the source electrode 110 and the drain electrode 111 may be formed after the opening 107a is formed, and the order of producing these falls within consideration of the production process of transistors.

Next, as shown in FIG. 2D, in the barrier layer 104 that is in the region of the opening 107a, the recess part 104a is formed to the middle part of the barrier layer 104 in the thickness direction (fourth step). Since the stopper layer 106 is formed in the embodiment, the recess part 104a is formed to the middle part of the barrier layer 104 in the thickness direction so as to penetrate through the stopper layer 106. The depth of the recess part 104a is set to fall within its range exceeding the thickness of the stopper layer 106 and not exceeding the sum of the thicknesses of the stopper layer 106 and the barrier layer 104. For example, the depth of the recess part 104a is typically set within the range between 5 nm and 20 nm when the thickness of the stopper layer 106 is 5 nm and the sum of the thicknesses of the stopper layer 106 and the barrier layer 104 is 20 nm.

For example, the recess part 104a can be formed by etching processing of forming an oxide layer through oxidation from the surface side and of removing the oxide layer. For example, using a mask pattern (not shown) having an opening at a region where the recess part 104a is to be formed, the stopper layer 106 and the barrier layer 104 are selectively oxidized from the surface side, and the oxide layer formed by this oxidation is selectively removed by wet etching.

For example, the formation of an oxide layer and the removal of the oxide layer mentioned above can be performed by alternate immersion in a hydrogen peroxide-based solution (oxidation process) and in a citric acid-based or phosphoric acid-based etchant (etching process). In the oxidation process, a very thin oxide layer with a sub-nanometer thickness is formed on the exposed surface of the layer to be etched, and in the etching process, the very thin oxide layer is removed, which enables the amount of etching to be accurately controlled with the number of repetitions of the two processes, not with the immersion (processing) time.

Moreover, the recess part 104a can also be formed by well-known atomic layer etching. In the atomic layer etching, for example, using a predetermined plasma processing apparatus, a chemical modification process on the outermost surface of atomic layers using plasma of chlorine gas and an etching process of the chemical modification layer using plasma of argon gas are alternately performed. Also with this etching processing method, the amount of etching can be accurately controlled with the number of repetitions of the two processes.

Next, as shown in FIG. 2E, by oxidizing the barrier layer 104 that is in the bottom part and the lateral surface of the recess part 104a, the gate insulating layer 109 composed of an oxide of a substance which the barrier layer 104 is composed of is formed (fifth step).

The formation of the gate insulating layer 109 by oxidation of the barrier layer 104 can be performed by wet processing using a solution containing an oxidizing agent, for example. In the wet processing, component substances such as In and Al are locally oxidized with the oxidizing agent such, for example, as hydrogen peroxide. This wet processing (fifth step) is performed continuously from the formation of the recess part 104a (fourth step) mentioned above, and the gate insulating layer 109 can be formed without drying the place to be processed after the wet etching in the recess part 104a.

As mentioned above, in the formation of the recess part 104a, the oxidation process with a solution of hydrogen peroxide and the etching process with a citric acid-based or phosphoric acid-based etchant are alternately performed to form the recess part 104a, and subsequently, the oxidation is performed by the oxidation process with a solution of hydrogen peroxide. In this processing, the formation of the recess part 104a and the formation of the gate insulating layer 109 can be continuously performed, which can prevent the processed place from being dried, and hence, an excellent interface, between the semiconductor and the oxide layer, which has few interface defects can be formed.

In this stage, oxidizing InAlAs which the barrier layer 104 is composed of forms oxides of In, Al, and As. Indium oxide (In₂O₃) has a relatively high dielectric constant, which is 10 to 20, and also has a relatively high bandgap, which is 2.5 to 3.5 eV. Moreover, aluminum oxide (Al₂O₃) has a dielectric constant, which is about 10, but has a very high bandgap, which is 6 to 9 eV. Accordingly, the gate insulating layer 109 formed by oxidizing the barrier layer 104 and composed of the aforementioned oxides has high dielectric constant and bandgap and is a layer with a high barrier to electrons. As a result, use of the gate insulating layer 109 can form an excellent MOS structure.

The gate insulating layer 109 formed by the aforementioned wet processing is composed of a layer of In oxide and a layer of Al oxide. For example, etching InAlAs with citric acid leads, under the conditions for this, to segregation of In₂O₃ onto the surface side (gate electrode side) and to formation of Al₂O₃ and indium aluminum oxide onto the inner side (channel layer side). In this case, the gate insulating layer 109 can be formed which has a high bandgap at its interface with the semiconductor and is composed of two layers or more of structural components having a high dielectric constant effective for concentrating the electric field on the gate electrode side and for restraining the short channel effect. As above, the gate insulating layer 109 can be composed from the structure of two layers or more of layer(s) of In oxide and layer(s) of Al oxide, and the structural component of each layer is composed of In oxide, Al oxide, or mixed oxide of these.

The thickness of the gate insulating layer 109 formed by the aforementioned wet processing can be accurately controlled in accordance with “Luke's model” by means of the immersion time in the processing liquid and the temperature of the processing liquid, and can be formed into any thickness within the range of 0.5 to 5 nm with excellent controllability.

The thickness of the gate insulating layer 109 is formed within a range not exceeding a half the sum of the thicknesses of the stopper layer 106 and the barrier layer 104. For example, when the sum of the thicknesses of the stopper layer 106 and the barrier layer 104 is 20 nm, the thickness of the gate insulating layer 109 can be set to 10 nm or less, typically about 2 nm of thickness, which is a tenth thereof.

Moreover, the formation (fifth step) of the gate insulating layer 109 through oxidation of the barrier layer 104 can also be performed, for example, by dry processing using plasma from gas containing oxygen. In this case, by performing the formation (fourth step) of the recess part 104a by atomic layer etching, the gate insulating layer 109 can be formed subsequently from this processing without releasing the processing atmosphere to ambient air, which can afford an especially excellent interface between the semiconductor and the insulating layer.

First, using a processing apparatus for performing the well-known atomic layer etching, the recess part 104a is formed by the atomic layer etching in a processing atmosphere obtained by hermetic sealing and decompression (fourth step). For example, using a predetermined processing apparatus, the recess part 104a is formed by alternately performing the chemical modification process on the outermost surface of atomic layers using plasma of chlorine gas and the etching process of the chemical modification layer using plasma of argon gas. Subsequently from this atomic layer etching, oxygen gas is introduced into the processing chamber without releasing the processing atmosphere (processing chamber) to ambient air, and plasma of the introduced oxygen gas is generated. With the action of the generated plasma of oxygen gas, the barrier layer 104 that is at the portion exposed on the lateral surface and the bottom surface of the recess part 104a is oxidized to form the gate insulating layer 109.

Notably, the gate insulating layer 109 can also be formed by, before introducing oxygen gas into the processing chamber, heating the target to be processed under a low vacuum to sublime and selectively remove As higher in vapor pressure than the other component elements, and then, oxidizing In and Al using the aforementioned oxygen plasma. Also in this formation of the gate insulating layer 109 by the dry processing, the thickness thereof can be accurately controlled with the power of the oxygen plasma and the sample temperature as with the aforementioned case of the wet processing.

After the formation of the gate insulating layer 109 as above, the gate electrode 108 that is arranged on the barrier layer 104 is formed such that a part of the gate electrode 108 penetrates into the recess part 104a in which the gate insulating layer 109 is formed (sixth step). This affords the field effect transistor shown in FIG. 1. For example, using, in the formation of the recess part 104a, a mask pattern having an opening at the place where the gate electrode 108 is to be formed, the gate insulating layer 109 is formed without this mask pattern removed. After the gate insulating layer 109 is formed, in the state where the aforementioned mask pattern is formed, a gate electrode material is deposited, for example, by a sputtering method. After that, removal (lift-off) of the mask pattern can form the gate electrode 108.

For example, when the gate insulating layer 109 is formed by dry processing, the aforementioned gate electrode material can be deposited while the vacuum state of the processing chamber where the gate insulating layer 109 is formed is being maintained. Forming the gate electrode 108 as above prevents contact of the surface of the gate insulating layer 109 with ambient air. As a result, contaminants and the like can be prevented from attaching onto the surface of the gate insulating layer 109 due to its contact with ambient air and the like. As a result, defects at the interface between the gate electrode 108 and the gate insulating layer 109 can be reduced, which is advantageous to improvement of the characteristics.

As described above, according to the present invention, since the gate insulating layer is used which is composed of an oxide of a substance which the barrier layer is composed of, a MOS-type field effect transistor having excellent characteristics can be manufactured in high throughput.

Notably, the present invention is not limited to the embodiment described above, but it is clear that those skilled in the art can carry out many modifications and combinations thereof without departing from the technical concepts of the present invention.

### REFERENCE SIGNS LIST

101 Semiconductor substrate

102 Buffer layer

103 Channel layer

104 Barrier layer

104a Recess part

105 Carrier supply layer

106 Stopper layer

107 Cap layer

108 Gate electrode

108a Penetration portion

108b Leg portion

108c Head portion

109 Gate insulating layer

110 Source electrode

111 Drain electrode

1. A semiconductor device comprising:
a buffer layer, a channel layer, a barrier layer, and a carrier supply layer which are formed on a semiconductor substrate;
a recess part formed, in the barrier layer, to a middle part of the barrier layer in a thickness direction;
a gate electrode formed on the barrier layer such that a part of the gate electrode penetrates into the recess part;
a source electrode and a drain electrode formed on the barrier layer such that the gate electrode is interposed between them;
a cap layer formed between both of the source electrode and the drain electrode and the barrier layer; and
a gate insulating layer formed between both of a bottom part and a lateral surface of the recess part and the gate electrode and composed of an oxide of a substance that the barrier layer is composed of.

2. The semiconductor device according to claim 1, wherein
the barrier layer is composed of InAlAs.

3. The semiconductor device according to claim 2, wherein
the gate insulating layer is composed of a layer of In oxide and a layer of Al oxide.

4. A manufacturing method of a semiconductor device, comprising:
a first step of providing a state where a buffer layer, a channel layer, a barrier layer, a carrier supply layer, and a cap layer are formed on a semiconductor substrate;
a second step of forming a source electrode and a drain electrode on the cap layer so as to be separate from each other;
a third step of forming an opening in the cap layer that is in a gate formation region between the source electrode and the drain electrode, the opening penetrating through the cap layer;
a fourth step of forming, in the barrier layer that is in a region of the opening, a recess part to a middle part of the barrier layer in a thickness direction;
a fifth step of forming a gate insulating layer composed of an oxide of a substance that the barrier layer is composed of by oxidizing the barrier layer that is in a bottom part and a lateral surface of the recess part; and
a sixth step of forming a gate electrode that is arranged on the barrier layer such that a part of the gate electrode penetrates into the recess part in which the gate insulating layer is formed.

5. The manufacturing method of a semiconductor device according to claim 4, wherein
the fifth step forms the gate insulating layer by wet processing using a solution containing an oxidizing agent.

6. The manufacturing method of a semiconductor device according to claim 5, wherein
the fourth step forms the recess part by wet etching, and
the fifth step forms, after the wet etching in the fourth step, the gate insulating layer without drying a place to be processed.

7. The manufacturing method of a semiconductor device according to claim 4, wherein
the fifth step forms the gate insulating layer by dry processing using plasma from gas containing oxygen.

8. The manufacturing method of a semiconductor device according to claim 5, wherein
the fourth step forms the recess part by atomic layer etching in a processing atmosphere obtained by hermetic sealing and decompression, and
the fifth step forms, subsequently from the atomic layer etching, the gate insulating layer without releasing the processing atmosphere to ambient air.
